(19) United States
(12) Patent Application Publication
(10) Pub. No.: US 2025/0170620 A1
(43) Pub. Date: May 29, 2025

(54) APPARATUS AND METHOD OF TREATING SUBSTRATE

(71) Applicant: SEMES CO., LTD., Cheonan-si (KR)

(72) Inventors: Hyun Woo BAE, Seoul (KR); Dae Hun KIM, Pyeongtaek-si (KR); Bu Young JUNG, Cheonan-si (KR); Jun Kil HWANG, Yongin-si (KR); Min Kyoung KIM, Cheonan-si (KR); Dong Geon LEE, Seoul (KR); Ji Su HONG, Asan-si (KR)

(73) Assignee: SEMES CO., LTD., Cheonan-si (KR)

(21) Appl. No.: 18/956,926

(22) Filed: Nov. 22, 2024

(30) Foreign Application Priority Data
Nov. 24, 2023 (KR) 10-2023-0165732

(51) Int. Cl. B08B 3/10; B08B 3/08

(52) U.S. Cl. CPC B08B 3/102; B08B 3/08; B08B 2203/007

(57) ABSTRACT

Disclosed is an apparatus for treating a substrate, the apparatus including: a process chamber for treating a substrate with a treatment solution; a treatment solution supply pipe for supplying a liquid used for a liquid treatment to the process chamber; a mixing unit connected to the treatment solution supply pipe and having a mixing space formed therein; a first liquid pipe for supplying a first liquid to the mixing space; a second liquid pipe for supplying a second liquid to the mixing space; an intake pipe for decompressing the mixing space; a first valve for regulating the supply of the first liquid to the mixing space; a second valve for regulating the supply of the second liquid to the mixing space; and an intake valve for regulating whether to decompress the mixing space, in which the mixing unit includes a body including the mixing space, and a first inlet port, a second inlet port, a third inlet port, and an outlet port connected with the mixing space, the outlet port is connected with the liquid supply pipe, the second inlet port is connected to the second liquid pipe, and the third inlet port is connected with the intake pipe.

### CROSS-REFERENCE TO RELATED APPLICATIONS

This application claims priority to and the benefit of Korean Patent Application No. 10-2023-0165732 filed in the Korean Intellectual Property Office on Nov. 24, 2023, the entire contents of which are incorporated herein by reference.

### TECHNICAL FIELD

The present invention relates to a substrate treating method and a substrate treating apparatus, and more particularly, to a substrate treating apparatus and a substrate treating method for treating a substrate by using a stabilized treatment solution.

### BACKGROUND ART

A semiconductor process includes a process of cleaning a thin film, foreign substances, particles, and the like on a substrate. These processes are accomplished by placing a substrate on a spin head with a patterned side facing up or down, supplying a treatment solution to the substrate while the spin head is rotated, and subsequently drying the wafer.

The substrate cleaning process consists of a chemical solution treatment process to etch or delaminate contaminants on the substrate by chemical reaction, a rinse process to wash the substrate treated with the chemical solution with deionized water, and a drying process to dry the rinse-treated substrate. Various types of chemical solutions are used for the above-mentioned chemical solution treatment process, and one of the chemical solutions is a chemical (sulfuric acid peroxide mixture (SPM)), which is a mixture of sulfuric acid (H₂SO₄) and a hydrogen peroxide solution (H₂O₂). FIG. 1 is a diagram schematically illustrating one example of a nozzle that mixes an SPM. Referring to FIG. 1, a nozzle 540 includes a body 550. The body 550 has a mixing space 552 and a discharge port 554. In the mixing space 552, the sulfuric acid solution and the hydrogen peroxide solution are mixed. The mixing space 552 is connected with a sulfuric acid supply line 510 and a hydrogen peroxide solution supply line 520. The sulfuric acid solution supplied through the sulfuric acid supply line 510 and the hydrogen peroxide solution supplied through the hydrogen peroxide solution supply line 520 are mixed. The mixed solution is discharged through the discharge port 554. The discharged mixture is applied to the substrate.

However, when the SPM is mixed in the nozzle 540 described above, the SPM is discharged in a state where the mixing reaction is not stabilized, so that a large amount of SPM may be scattered and a large amount of fume may be generated.

### SUMMARY OF THE INVENTION

The present invention has been made in an effort to provide a substrate treating apparatus and method capable of suppressing the generation of scattering and fume of a treatment solution when a stabilized treatment solution is supplied to a substrate to treat the substrate.

The present invention has also been made in an effort to provide a substrate treating apparatus and method capable of preventing a treatment solution remaining in a nozzle from dripping onto a substrate.

The problem to be solved by the present invention is not limited to the above-mentioned problems, and the problems not mentioned will be clearly understood by those skilled in the art from the descriptions below.

An exemplary embodiment of the present invention provides an apparatus for treating a substrate, the apparatus including: a process chamber for treating a substrate with a treatment solution; a treatment solution supply pipe for supplying a liquid used for a liquid treatment to the process chamber; a mixing unit connected to the treatment solution supply pipe and having a mixing space formed therein; a first liquid pipe for supplying a first liquid to the mixing space; a second liquid pipe for supplying a second liquid to the mixing space; an intake pipe for decompressing the mixing space; a first valve for regulating the supply of the first liquid to the mixing space; a second valve for regulating the supply of the second liquid to the mixing space; and an intake valve for regulating whether to decompress the mixing space, in which the mixing unit includes a body including the mixing space, and a first inlet port, a second inlet port, a third inlet port, and an outlet port connected with the mixing space, the outlet port is connected with the treatment solution supply pipe, the second inlet port is connected with the second liquid pipe, and the third inlet port is connected with the intake pipe.

According to the exemplary embodiment, the second inlet port may be disposed closer to the outlet port than the first inlet port.

According to the exemplary embodiment, the first inlet port may be disposed further from the outlet port than the second inlet port and the third inlet port.

According to the exemplary embodiment, in the second liquid pipe or a second liquid supply source in which the second liquid is stored, a heater for heating the second liquid may be installed, and the third inlet port may be provided between the first inlet port and the second inlet port.

According to the exemplary embodiment, the outlet port may be located on a first wall among walls forming the mixing space, the first inlet port, the second inlet port, and the intake port may be located on a second wall among the walls forming the mixing space, the second wall may be adjacent to the first wall, and the second wall may be perpendicular to the first wall.

According to the exemplary embodiment, the apparatus may further include a first driver for moving the first valve in a direction toward or away from an end portion of the first inlet port, in which the supply of the first liquid may be blocked when the first valve is in contact with the first inlet port, and the first liquid is supplied when the first valve is spaced away from the first inlet port, the apparatus may further include a second driver for moving the second valve in a direction toward or away from an end portion of the second inlet port, in which the supply of the second liquid may be blocked when the second valve is in contact with the second inlet port, and the second liquid is supplied when the second valve is spaced away from the second inlet port, and the apparatus may further include a third driver for moving the third valve in a direction toward or away from an end portion of the third inlet port, in which decompression of the mixing space may be blocked when the third valve is in contact with the third inlet port, and the mixing space may be decompressed when the third valve is spaced away from the third inlet port.

According to the exemplary embodiment, the mixing unit may further include a controller, and the controller may perform: a mixed solution treatment operation of opening the first valve and the second valve to generate a mixed solution in which the first liquid and the second liquid are mixed in the mixing space, and supplying the mixed solution to the substrate to treat the substrate; and a first liquid treatment operation of, after the mixed solution treatment operation, closing the second valve and supplying the first liquid to the substrate from the mixing space to treat the substrate.

According to the exemplary embodiment, the controller may perform a decompression operation of, after the first liquid treatment operation, closing the first valve and the second valve and opening the third valve to decompress the mixing space and remove the liquid in the mixing space.

According to the exemplary embodiment, the first liquid may be a hydrogen peroxide solution (H₂O₂), and the second liquid may be sulfuric acid (H₂SO₄).

According to the exemplary embodiment, the apparatus may further include an inline-mixer installed on the treatment solution supply pipe.

Another exemplary embodiment of the present invention provides a method of treating a substrate, the method including: a mixed solution treatment operation of generating a mixed solution in which the first liquid and the second liquid are mixed in the mixing space, and supplying the mixed solution to the substrate to treat the substrate; a first liquid treatment operation of, after the mixed solution treatment operation, supplying the first liquid to the substrate from the mixing space to treat the substrate; and a decompression operation of decompressing the mixing space to remove the mixed solution, the first liquid, or the second liquid in the mixing space.

According to the exemplary embodiment, the mixed solution treatment operation may include supplying the first liquid to a location further from the outlet port than the second liquid.

According to the exemplary embodiment, the first liquid treatment operation may include supplying the first liquid from a location farthest from the outlet port.

According to the exemplary embodiment, the mixed solution treatment operation may include supplying the second liquid at a higher temperature than the first liquid, and the first liquid and the second liquid may be supplied into the mixing space at the most spaced apart positions.

According to the exemplary embodiment, the mixed solution treatment operation may include mixing the first liquid and the second liquid secondarily by an inline-mixer installed in the treatment solution supply pipe.

According to the exemplary embodiment, the first liquid may be a hydrogen peroxide solution (H₂O₂), and the second liquid may be sulfuric acid (H₂SO₄).

Still another exemplary embodiment of the present invention provides an apparatus for treating a substrate, the apparatus including: a process chamber for liquid-treating a substrate; a treatment solution supply pipe for supplying a liquid used for the liquid treatment to the process chamber; a mixing unit connected to the treatment solution supply pipe and having a mixing space formed therein; a hydrogen peroxide solution supply pipe for supplying a hydrogen peroxide solution (H₂O₂) to the mixing space; a sulfuric acid supply pipe for supplying sulfuric acid (H₂SO₄) to the mixing space; an intake pipe for decompressing the mixing space; a first valve for regulating the supply of the hydrogen peroxide solution to the mixing space; a second valve for regulating the supply of the sulfuric acid to the mixing space; and an intake valve for regulating whether to decompress the mixing space, in which the mixing unit includes a body including the mixing space, and a first inlet port, a second inlet port, a third inlet port, and an outlet port connected with the mixing space, the outlet port is connected with the liquid supply pipe, the first inlet port is connected with the hydrogen peroxide solution supply pipe, the second inlet port is connected with the sulfuric acid supply pipe, the third inlet port is connected with the intake pipe, the first inlet port is disposed further from the outlet port than the second inlet port and the third inlet port, and a heater for heating the sulfuric acid is installed at the sulfuric acid supply pipe or a sulfuric acid supply source in which the sulfuric acid is stored.

According to the exemplary embodiment, the second inlet port may be located between the first inlet port and the third inlet port.

According to the exemplary embodiment, the outlet port may be located on a first wall among walls forming the mixing space, the first inlet port, the second inlet port, and the intake port may be located on a second wall among the walls forming the mixing space, the second wall may be adjacent to the first wall, and the second wall may be perpendicular to the first wall.

According to the exemplary embodiment, the apparatus may further include an inline-mixer installed on the treatment solution supply pipe.

According to the exemplary embodiment, the apparatus may further include a first driver for moving the first valve in a direction toward or away from an end portion of the first inlet port, in which the supply of the hydrogen peroxide solution may be blocked when the first valve is in contact with the first inlet port, and the hydrogen peroxide solution is supplied when the first valve is spaced away from the first inlet port, the apparatus may further include a second driver for moving the second valve in a direction toward or away from an end portion of the second inlet port, in which the supply of the sulfuric acid may be blocked when the second valve is in contact with the second inlet port, and the sulfuric acid is supplied when the second valve is spaced away from the second inlet port, and the apparatus may further include a third driver for moving the third valve in a direction toward or away from an end portion of the third inlet port, in which decompression of the mixing space may be blocked when the third valve contacts the third inlet port, and the mixing space is decompressed when the third valve is spaced away from the third inlet port.

According to the exemplary embodiment of the present invention, it is possible to suppress scattering of a treatment solution and the generation of fumes when treating a substrate by supplying a stabilized treatment solution to the substrate.

According to the exemplary embodiment of the present invention, it is possible to prevent a treatment solution remaining in a nozzle from falling onto the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating one example of a nozzle that mixes an SPM.

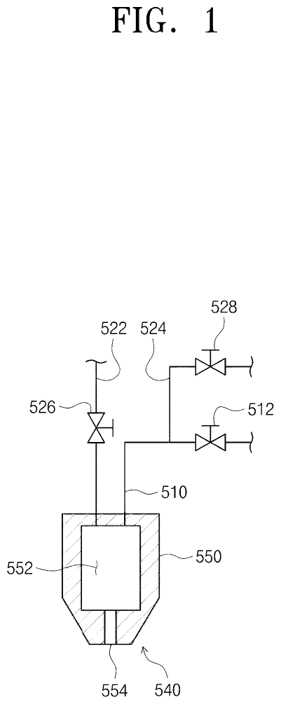

FIG. 2 is a top plan view schematically illustrating a substrate treating apparatus according to an exemplary embodiment of the present invention.

FIG. 3 is a diagram schematically illustrating an exemplary embodiment of a liquid treating chamber of FIG. 2.

FIG. 4 is a cross-sectional view illustrating a cross-section of a mixing unit according to an exemplary embodiment of the present invention.

FIG. 5 is a flowchart illustrating a method of treating a substrate by using a substrate treating apparatus according to an exemplary embodiment of the present invention.

FIG. 6 is a diagram illustrating a view of a mixing unit during a mixed solution treatment operation.

FIG. 7 is a diagram illustrating a view of the mixing unit during a first liquid treatment operation.

FIG. 8 is a diagram illustrating a view of the mixing unit during a decompression operation.

FIG. 9 is a diagram illustrating a view of the mixing unit according to another exemplary embodiment of the present invention.

FIG. 10 is a diagram showing a view of the mixing unit according to another exemplary embodiment of the present invention.

FIG. 11 is a diagram illustrating a view of the mixing unit according to another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

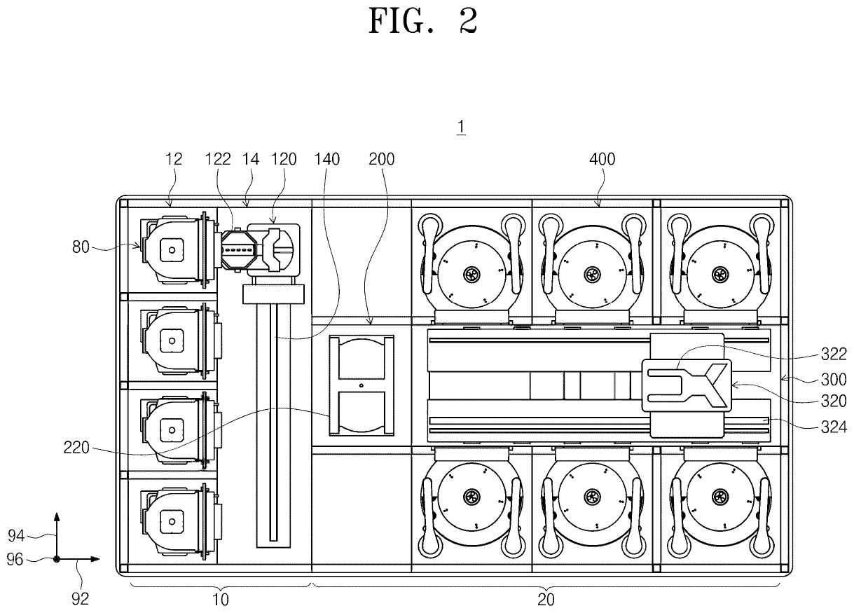

FIG. 2 is a top plan view schematically illustrating a substrate treating apparatus according to an exemplary embodiment of the present invention.

Referring to FIG. 2, a substrate treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer unit 200, a conveying chamber 300, and a process chamber 400. The buffer unit 200 provides a space in which the substrate W loaded into the treating module 20 and the substrate W unloaded from the treating module 20 stay temporarily. The process chamber 400 supplies a liquid onto the substrate W to perform a treatment process of liquid-treating the substrate W. The transfer chamber 300 transfers the substrate W between the buffer unit 200 and the liquid process chamber 400.

The transfer chamber 300 may be provided so that a longitudinal direction is the first direction 92. The buffer unit 200 may be disposed between the index module 10 and the transfer chamber 300. A plurality of liquid process chambers 400 are provided, and may be disposed at a lateral portion of the transfer chamber 300. The liquid process chamber 400 and the transfer chamber 300 may be disposed along the second direction 94. The buffer unit 200 may be located at one end of the transfer chamber 300.

In one example, the liquid process chambers 400 are disposed on opposite sides of the transfer chamber 300, respectively. At the opposite sides of the transfer chamber 300, the liquid process chambers 400 may be provided in an arrangement of A×B (each of A and B is 1 or a natural larger than 1) in the first direction 92 and the third direction 96, respectively.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forward and backward, rotatable about the third direction 96, and movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

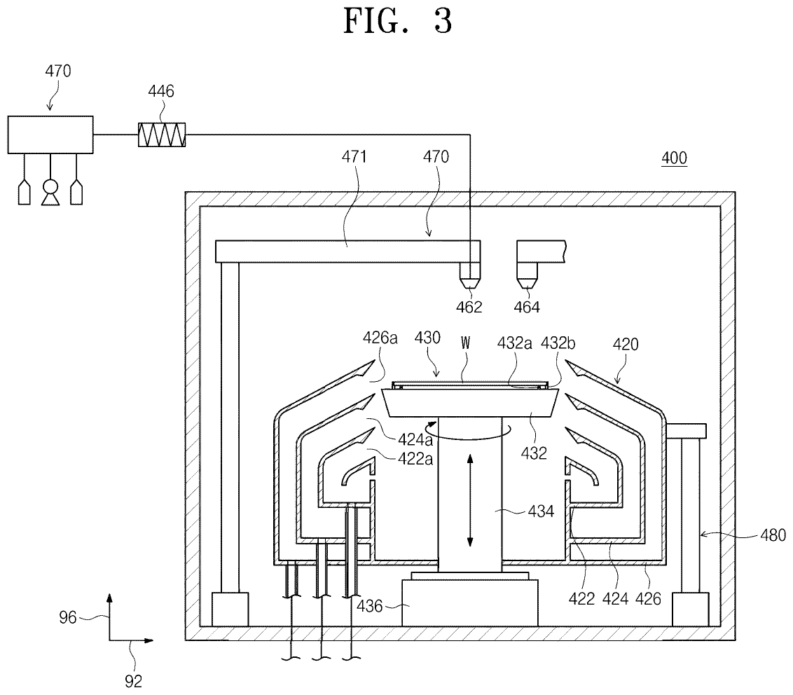

FIG. 3 is a diagram schematically illustrating one exemplary embodiment of the process chamber 400 of FIG. 2. Referring to FIG. 3, the process chamber 400 may include a housing 410, a cup 420, a support unit 430, a mixing unit 440, pipes 451, 452, 453, and 454, valves 442a, 443a, and 444a, a nozzle unit 470, and a lifting unit 480.

The housing 410 is provided in a generally rectangular parallelepiped shape. The cup 420, the support unit 430, and the liquid supply unit 470 are disposed in the housing 410.

The cup 420 has a treatment space with an open top, and the substrate W is liquid-treated in the treatment space. The support unit 430 supports the substrate W in the treatment space. The nozzle unit 470 supplies a liquid onto the substrate W supported on the support unit 430. The liquid may be provided in a plurality of types, and may be sequentially supplied onto the substrate W. The lifting unit 480 adjusts a relative height between the cup 420 and the support unit 430.

According to the example, the cup 420 includes a plurality of recovery containers 422, 424, and 426. Each of the recovery containers 422, 424, and 426 has a recovery space of recovering the liquid used for the treating of the substrate. Each of the recovery containers 422, 424, and 426 is provided in a ring shape surrounding the support unit 430. When the liquid treatment process is in progress, the treatment solution scattered by the rotation of the substrate W is introduced into the recovery space through inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be located above a first inlet 422a, which introduces the liquid into the first recovery container 422, and a third inlet 426a, which introduces the liquid into the third recovery container 426, may be located above the second inlet 424a.

The support unit 2640 has a support plate 2642 and a drive shaft 430. An upper surface of the support plate 432 may be provided in a generally circular shape, and may have a diameter larger than a diameter of the substrate W. In the center portion of the support plate 432, a support pin 442a is provided to support the rear surface of the substrate W, and the support pin 442a is provided with its upper end protruding from the support plate 432 so that the substrate W is spaced apart from the support plate 432 by a certain distance. A chuck pin 432b is provided to an edge of the support plate 442. The chuck pin 432b is provided to protrude upward from the support plate 430, and supports the lateral portion of the substrate W so that the substrate W is not separated from the support unit 440 when the substrate W is rotated. The drive shaft 434 is driven by a driver 446, is connected to the center of the bottom surface of the substrate W, and rotates the support plate 432 with respect to the central axis thereof.

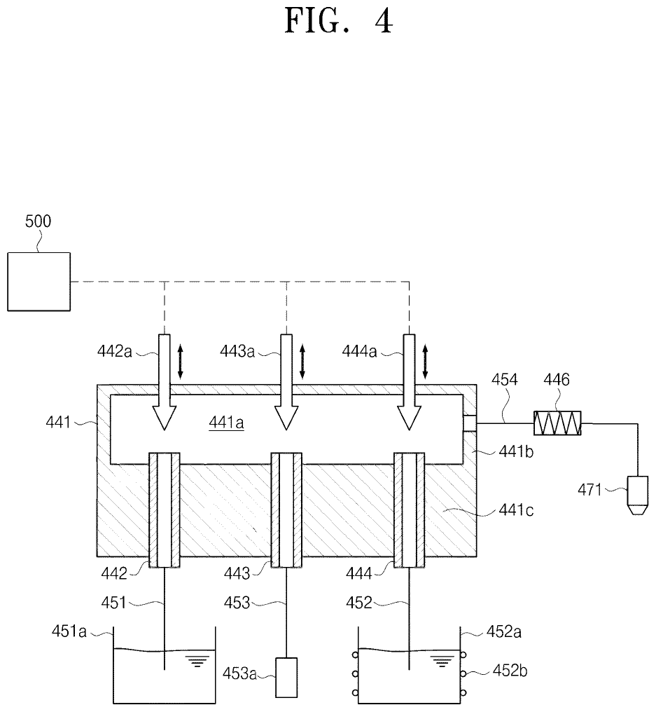

FIG. 4 is a cross-sectional view illustrating a cross-section of a mixing unit according to an exemplary embodiment of the present invention. Referring to FIG. 4, the mixing unit 440 includes a body 441 and ports 442, 443, 444, and 445. The body 441 provides a mixing space 441a. A first liquid and a second liquid are supplied into the mixing space 441a. In one example, the first liquid may be a hydrogen peroxide solution (H₂O₂). Further, in one example, the second liquid may be a sulfuric acid (H₂SO₄) solution. The mixing space 441a may be a flow path through which the first liquid and the second liquid flow. Further, the mixing space 441a may be a mixing space where the first liquid and the second liquid are mixed. The body 441 may include a first wall 441b and a second wall 441c. The first wall 441b may be perpendicular to the second wall 441c. In one example, the body 441 may be provided in a cuboidal shape, and the second wall 441c may be provided with a larger area than the first wall 441b. An outlet port 445 may be formed in the first wall 441b. A first inlet port 442, a second inlet port 443, and a third inlet port 444 may be formed in the second wall 431c. The first inlet port 442, the second inlet port 443, and the third inlet port 444 may be formed along the longitudinal direction. The second inlet port 443 may be disposed closer to the outlet port 445 than the first inlet port 442. Further, the first inlet port 442 may be disposed further from the outlet port 445 than the second inlet port 443 and the third inlet port 444. Accordingly, the first inlet port 442, the third inlet port 444, and the second inlet port 443 may be disposed in a sequence, and the outlet port 445 may be disposed adjacent to the second inlet port 443. The second wall 441c may be provided thicker than the first wall 441b. Accordingly, the first inlet port 442, the second inlet port 443, and the third inlet port 444 may be provided longer than the outlet port 445. However, the present invention is not limited thereto, and the thickness of the first wall 441b and the second wall 441c can be freely varied in various other combinations, variations, and circumstances.

The first inlet port 442 may be equipped with a first valve 442a to regulate the first inlet port 442. The substrate treating apparatus may also include a first driver (not shown) that moves the first valve 442a in a direction toward or away from an end portion of the first inlet port 442. Thereby, the supply of the first liquid may be blocked when the first valve 442a is in contact with the first inlet port 442, and the first liquid may be supplied when the first valve 442a is spaced away from the first inlet port 442.

The second inlet port 443 may be equipped with a second valve 443a that regulates the second inlet port 443. The substrate treating apparatus may also include a second driver (not shown) that moves the second valve 443a in a direction toward or away from an end portion of the second inlet port 443. Thereby, the supply of the second liquid may be blocked when the second valve 443a is in contact with the second inlet port 443, and the second liquid may be supplied when the second valve 443a is spaced away from the second inlet port 443.

The third inlet port 444 may be equipped with a third valve 444a that regulates the third inlet port 444. The substrate treating apparatus may also include a third driver (not shown) that moves the third valve 444a in a direction toward or away from an end portion of the third inlet port 444. Thereby, decompression of the mixing space 441a may be blocked when the third valve 444a is in contact with the third inlet port 444, and decompression of the mixing space 441a may occur when the third valve 444a is spaced away from the third inlet port 444.

A first inlet port 442 is connected with a first liquid pipe 451 that supplies first liquid. The second inlet port 443 is connected with a second liquid pipe 452 that supplies the second liquid. The third inlet port 444 is connected with an intake pipe 453 that decompresses the mixing space 441a. The outlet port 445 is connected with a treatment solution supply pipe 454 that supplies a liquid used for a liquid treatment to the process chamber 400. The first liquid pipe 451 connects the mixing unit 440 with the first liquid supply source 451a, which stores the first liquid. The first liquid pipe 451 supplies the first liquid to the mixing space 441a. The second liquid pipe 452 connects the mixing unit 440 with the second liquid supply source 442a, which stores the second liquid. The second liquid pipe 452 supplies the second liquid to the mixing space 441a. The second liquid pipe 452 or the second liquid supply source 452a may be equipped with a heater 452b that heats the second liquid. The intake pipe 453 decompresses the mixing space 441a. A decompressing member may be installed in the intake pipe. In one example, a pump 453a may be provided as the decompressing member.

The mixing unit 440 may further include an inline-mixer 446. The inline-mixer 446 may be installed in the treatment solution supply pipe 454. Thereby, the first liquid and the second liquid may be mixed primarily in the mixing space 441a and mixed secondarily in the inline-mixer 446.

The nozzle unit 470 may include a first nozzle 472 and a second nozzle 474. The first nozzle 472 supplies the treatment solution onto the substrate W. The treatment solution may be a liquid having a temperature higher than room temperature. In one example, the treatment solution may be a sulfuric acid peroxide mixture (SPM). The SPM can be a mixed solution (SPM) of high-temperature sulfuric acid and a room-temperature hydrogen peroxide solution. The second nozzle 474 supplies water onto the substrate W. The water may be pure water or deionized water.

The first nozzle 472 and the second nozzle 474 are respectively supported on different arms 472, respectively, and the arms 461 may be moved independently. Optionally, the first nozzle 472 and the second nozzle 474 may be mounted on the same arm and moved at the same time.

Optionally, the nozzle unit 470 may further include one or more nozzles, in addition to the first nozzle 472 and the second nozzle 474. Additional nozzles may supply different types of treatment solutions to the substrate. For example, the other type of treatment solution may be an acid solution or a base solution for removing foreign substances on the substrate. In addition, another type of treatment solution may be alcohol having surface tension lower than that of water. For example, the alcohol may be isopropyl alcohol.

The lifting unit 480 moves the cup 420 in the up and down direction. By the up and down movement of the cup 420, a relative height between the cup 420 and the substrate W is changed. This changes the recovery containers 422, 424, and 426 for recovering the treatment solution depending on the type of liquid supplied to the substrate W, so that the liquids may be recovered separately. Unlike the description, the cup 420 may be fixedly installed, and the lifting unit 480 may move the support unit 430 in the vertical direction.

Further, the mixing unit 440 may further include a controller 500. The controller 500 may control the substrate treating apparatus of the present invention. The following describes a method of treating a substrate by using the substrate treating apparatus via the controller 500.

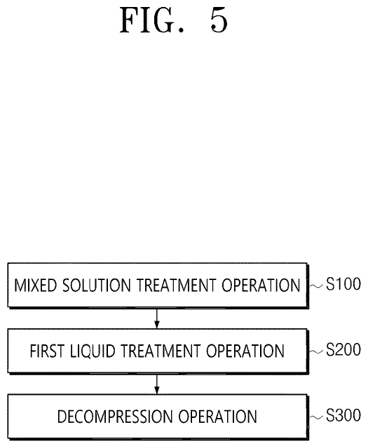

FIG. 5 is a flowchart illustrating a method of treating a substrate by using the substrate treating apparatus according to an exemplary embodiment of the present invention. Referring to FIG. 5, a substrate treating method may include a mixed solution treatment operation S100, a first liquid treatment operation S200, and a decompression operation S300.

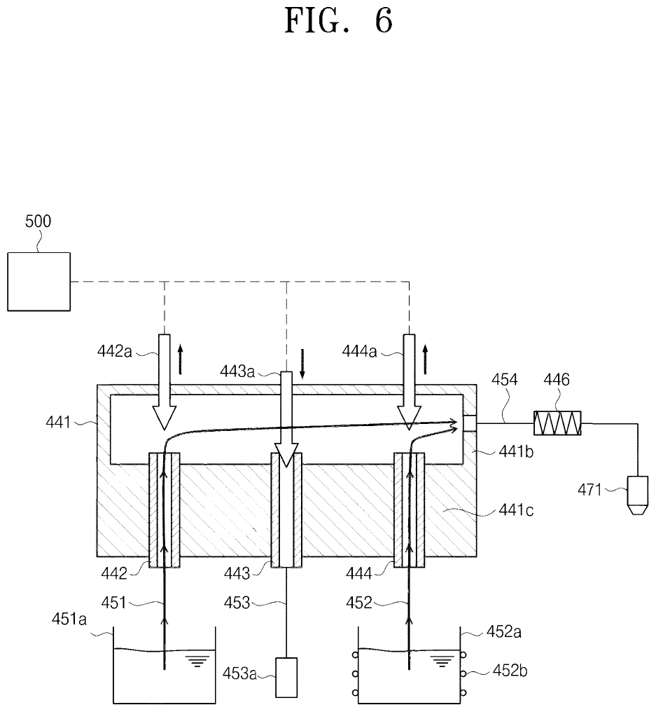

FIG. 6 is a diagram illustrating a view of a mixing unit during the mixed solution treatment operation. Referring to FIG. 6, during the mixed solution treatment operation S100, the first liquid and the second liquid are mixed. The first liquid and the second liquid may be mixed in the mixing space 441a. Additionally, when the inline-mixer 446 is installed, the first liquid and the second liquid may be further mixed. The controller 500 opens the first valve 442a and the second valve 442b and closes the third valve 442c. The first liquid and the second liquid are supplied to the mixing space 441a and mixed. The mixed solution is then supplied to the substrate W through the treatment solution supply pipe 454 through the outlet port 445. The substrate W is then treated with the mixed solution. The substrate W may be cleaned by the mixed solution. In one example, the mixed solution may be a sulfuric acid and peroxide mixture (SPM).

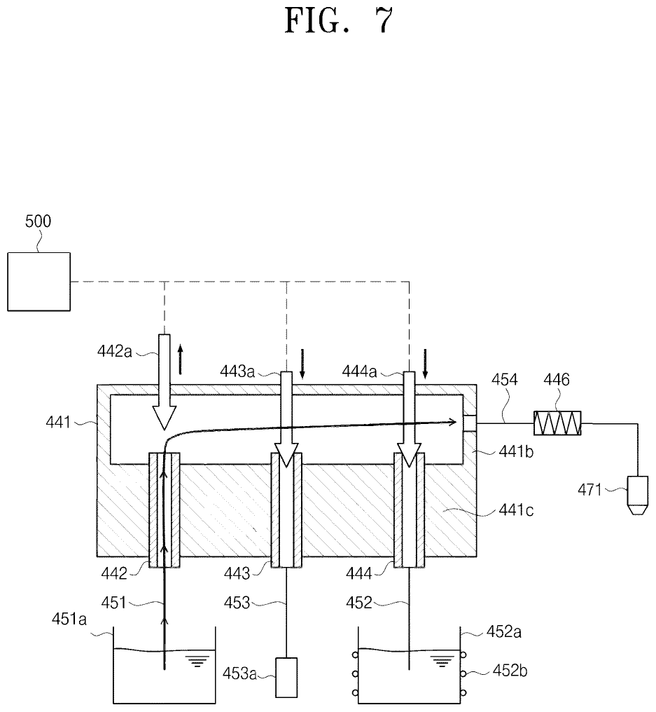

FIG. 7 is a diagram illustrating a view of the mixing unit during the first liquid treatment operation. Referring to FIG. 7, after the mixed solution treatment operation S100, a first solution treatment operation S200 may be performed. During the first liquid treatment operation S200, the first liquid cleans the substrate W. The controller 500 opens the first valve 442a, and closes the second valve 443a and the third valve 444a. Only the first liquid is supplied to the mixing space 441a. The first liquid is then supplied to the substrate W via the treatment solution supply pipe 454 through the outlet port 445. The first liquid may clean any residual mixed solution or second liquid on the substrate W. Further, during the first liquid treatment operation S200, the first liquid may clean the second liquid or the mixed solution residing in the mixing space 441a.

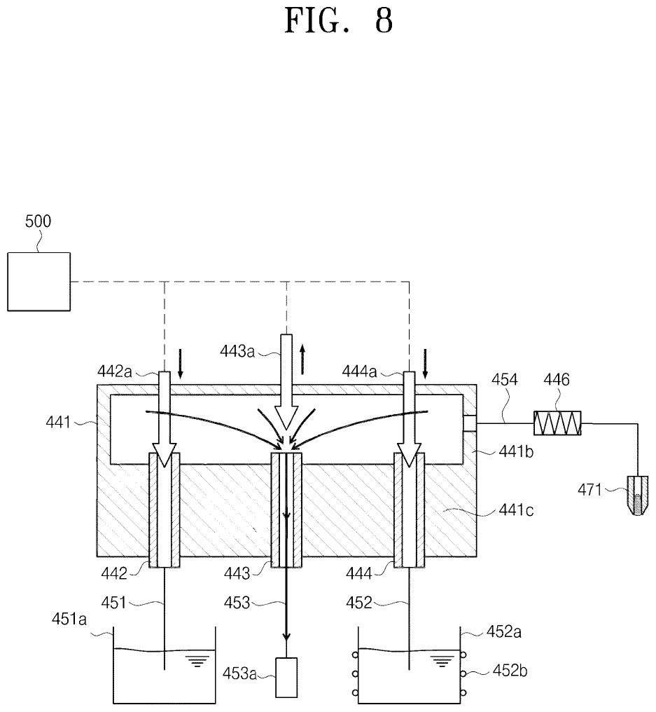

FIG. 8 is a diagram illustrating a view of the mixing unit during the decompression operation. Referring to FIG. 8, after the first liquid treatment operation S200, the decompression operation S300 may be performed. During the decompression operation S300, the mixing space 441a is decompressed. Thereby, the first liquid, the second liquid, or the treatment solution remaining in the mixing space 441a may be removed. In addition, the treatment solution remaining in the nozzle unit 470 can be sucked back to prevent the treatment solution from dripping onto the substrate W.

According to the exemplary embodiment of the present invention, instead of mixing the first liquid and the second liquid in the nozzle, by mixing the first liquid and the second liquid in the mixing unit 440 in advance, the treatment solution can be supplied in a state in which the mixing reaction of the generated treatment solution is stabilized. This can suppress the scattering of the treatment solution and fume generated when the treatment solution is discharged.

Additionally, by supplying the first liquid at a greater distance from the outlet port 445 than the second liquid, the efficiency with which the first liquid cleans the second liquid can be improved.

Furthermore, by supplying the first liquid farthest away from the outlet port 445, the cleaning efficiency can be increased by maximizing the extent of the mixing space 441a that the first liquid can clean.

Furthermore, by spacing the locations where the first and second liquids are supplied as far apart as possible, temperature interference between the first liquid and the hotter second liquid can be avoided. By minimizing the temperature of the second liquid being lowered by the first liquid, the temperature of the treatment solution generated by mixing the first liquid and the second liquid can be kept as high as possible, thereby improving the cleaning efficiency by the treatment solution.

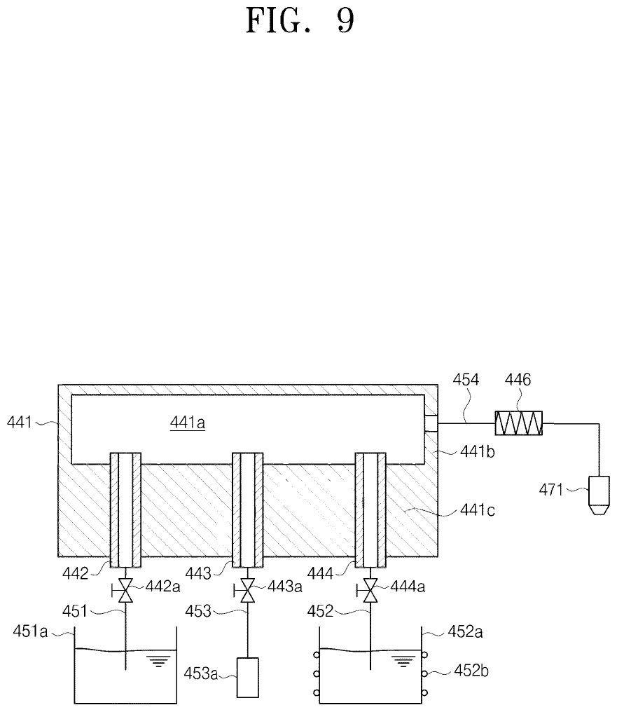

In the examples described above, the present invention has been described based on the case where the valves 442a, 443a, and 444a contact the end portions of the ports 442, 443, 444, and 445 to regulate whether the pipes 451, 452, 453, and 454 are open or closed as the example. However, the present invention is not limited thereto, and any configuration that is capable of regulating whether the mixing space 441a is connected to the respective pipes 451, 452, 453, and 454 is sufficient. FIG. 9 is a diagram illustrating a view of the mixing unit according to another exemplary embodiment of the present invention. Referring to FIG. 9, the valves 442a, 443a, and 444a may be provided in the form of an open/close valve on the pipes 451, 452, 453, 454, respectively.

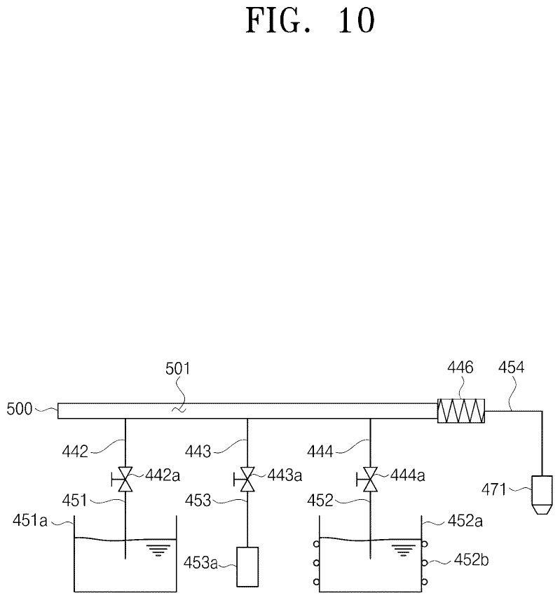

Furthermore, in the example described above, the present invention has been described based on the case where the mixing unit 440 includes the body 441 and the ports 442, 443, 444, and 445 as the example. However, the present invention is not limited thereto, and the mixing unit 440 may also be provided in the form of a manifold, as shown in FIG. 10. When the mixing unit 440 is provided in the manifold form, the ports 442, 443, 444, and 445 may be omitted and the pipes 451, 452, and 453 and the inline-mixer 446 may be connected directly to the manifold pipe 500 that provides a flow path 501 through which first and second liquids flow.

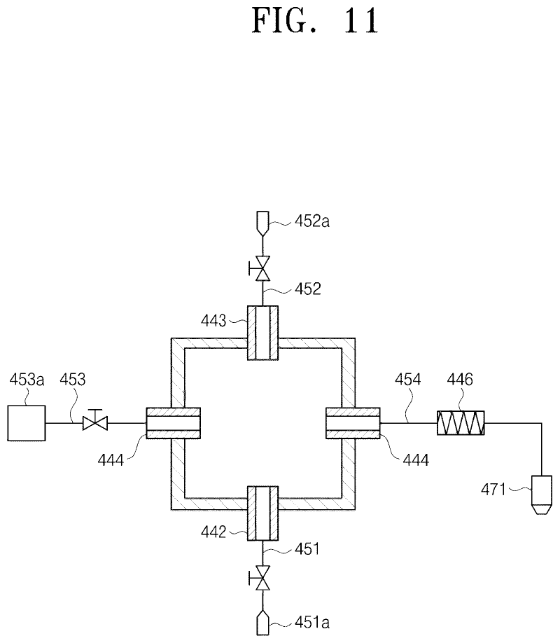

Further, in the example described above, the present invention has been described based on the case where the first inlet port 442, the second inlet port 443, and the third inlet port 444 are provided in the second wall 431c as the example. However, the present invention is not limited thereto, and the first inlet port 442, the second inlet port 443, and the third inlet port 444 may also be provided in the form of a four-way valve, as shown in FIG. 11. In this case, the first inlet port 442, the second inlet port 443, the third inlet port 444, and the outlet port 445 may be disposed in a direction facing each other.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. An apparatus for treating a substrate, the apparatus comprising:
a process chamber for treating a substrate with a treatment solution;
a treatment solution supply pipe for supplying a liquid used for a liquid treatment to the process chamber;
a mixing unit connected to the treatment solution supply pipe and having a mixing space formed therein;
a first liquid pipe for supplying a first liquid to the mixing space;
a second liquid pipe for supplying a second liquid to the mixing space;
an intake pipe for decompressing the mixing space;
a first valve for regulating the supply of the first liquid to the mixing space;
a second valve for regulating the supply of the second liquid to the mixing space; and
an intake valve for regulating whether to decompress the mixing space,
wherein the mixing unit includes a body including the mixing space, and a first inlet port, a second inlet port, a third inlet port, and an outlet port connected with the mixing space,
the outlet port is connected with the treatment solution supply pipe,
the first inlet port is connected with the first liquid pipe,
the second inlet port is connected with the second liquid pipe, and
the third inlet port is connected with the intake pipe.

2. The apparatus of claim 1, wherein the second inlet port is disposed closer to the outlet port than the first inlet port.

3. The apparatus of claim 1, wherein the first inlet port is disposed further from the outlet port than the second inlet port and the third inlet port.

4. The apparatus of claim 2, wherein in the second liquid pipe or a second liquid supply source in which the second liquid is stored, a heater for heating the second liquid is installed, and
the third inlet port is provided between the first inlet port and the second inlet port.

5. The apparatus of claim 1, wherein the outlet port is located on a first wall among walls forming the mixing space,
the first inlet port, the second inlet port, and the intake port are located on a second wall among the walls forming the mixing space,
the second wall is adjacent to the first wall, and
the second wall is perpendicular to the first wall.

6. The apparatus of claim 1, further comprising:
a first driver for moving the first valve in a direction toward or away from an end portion of the first inlet port,
wherein the supply of the first liquid is blocked when the first valve is in contact with the first inlet port, and the first liquid is supplied when the first valve is spaced away from the first inlet port,
the apparatus further comprises a second driver for moving the second valve in a direction toward or away from an end portion of the second inlet port,
wherein the supply of the second liquid is blocked when the second valve is in contact with the second inlet port, and the second liquid is supplied when the second valve is spaced away from the second inlet port,
the apparatus further comprises a third driver for moving the third valve in a direction toward or away from an end portion of the third inlet port,
wherein decompression of the mixing space is blocked when the third valve is in contact with the third inlet port, and the mixing space is decompressed when the third valve is spaced away from the third inlet port.

7. The apparatus of claim 1, wherein the mixing unit further includes a controller, and
the controller performs:
a mixed solution treatment operation of opening the first valve and the second valve to generate a mixed solution in which the first liquid and the second liquid are mixed in the mixing space, and supplying the mixed solution to the substrate to treat the substrate;
a first liquid treatment operation of, after the mixed solution treatment operation, closing the second valve and supplying the first liquid to the substrate from the mixing space to treat the substrate, and
a decompression operation of, after the first liquid treatment operation, closing the first valve and the second valve and opening the third valve to decompress the mixing space and remove the liquid in the mixing space.

8. The apparatus of claim 1, wherein the first liquid is a hydrogen peroxide solution (H₂O₂), and
the second liquid is sulfuric acid (H₂SO₄).

9. The apparatus of claim 1, further comprising:
an inline-mixer installed on the treatment solution supply pipe.

10.-15. (canceled)

16. An apparatus for treating a substrate, the apparatus comprising:
a process chamber for liquid-treating a substrate;
a treatment solution supply pipe for supplying a liquid used for the liquid treatment to the process chamber;
a mixing unit connected to the treatment solution supply pipe and having a mixing space formed therein;
a hydrogen peroxide solution supply pipe for supplying a hydrogen peroxide solution (H₂O₂) to the mixing space;
a sulfuric acid supply pipe for supplying sulfuric acid (H₂SO₄) to the mixing space;
an intake pipe for decompressing the mixing space;
a first valve for regulating the supply of the hydrogen peroxide solution to the mixing space;
a second valve for regulating the supply of the sulfuric acid to the mixing space; and
an intake valve for regulating whether to decompress the mixing space,
wherein the mixing unit includes a body including the mixing space, and a first inlet port, a second inlet port, a third inlet port, and an outlet port connected with the mixing space,
the outlet port is connected with the liquid supply pipe,
the first inlet port is connected with the hydrogen peroxide solution supply pipe,
the second inlet port is connected with the sulfuric acid supply pipe,
the third inlet port is connected with the intake pipe,
the first inlet port is disposed further from the outlet port than the second inlet port and the third inlet port, and
a heater for heating the sulfuric acid is installed at the sulfuric acid supply pipe or a sulfuric acid supply source in which the sulfuric acid is stored.

17. The apparatus of claim 16, wherein the second inlet port is located between the first inlet port and the third inlet port.

18. The apparatus of claim 17, wherein the outlet port is located on a first wall among walls forming the mixing space,
the first inlet port, the second inlet port, and the intake port are located on a second wall among the walls forming the mixing space,
the second wall is adjacent to the first wall, and
the second wall is perpendicular to the first wall.

19. The apparatus of claim 18, further comprising:
an inline-mixer installed on the treatment solution supply pipe.

20. The apparatus of claim 19, further comprising:
a first driver for moving the first valve in a direction toward or away from an end portion of the first inlet port,
wherein the supply of the hydrogen peroxide solution is blocked when the first valve is in contact with the first inlet port, and the hydrogen peroxide solution is supplied when the first valve is spaced away from the first inlet port,
the apparatus further comprises a second driver for moving the second valve in a direction toward or away from an end portion of the second inlet port,
wherein the supply of the sulfuric acid is blocked when the second valve is in contact with the second inlet port, and the sulfuric acid is supplied when the second valve is spaced away from the second inlet port,
the apparatus further comprises a third driver for moving the third valve in a direction toward or away from an end portion of the third inlet port,
wherein decompression of the mixing space is blocked when the third valve contacts the third inlet port, and the mixing space is decompressed when the third valve is spaced away from the third inlet port.
